(19) United States
(12) Patent Application Publication
(10) Pub. No.: US 2026/0153723 A1
(43) Pub. Date: Jun. 4, 2026

(54) DRIVE DEVICE, OPTICAL SYSTEM AND LITHOGRAPHY APPARATUS

(71) Applicant: Carl Zeiss SMT GmbH, Oberkochen (DE)

(72) Inventors: Oliver HERBST, Aalen (DE); Stefan WALZ, Schwaebisch Gmuend (DE)

(21) Appl. No.: 19/455,264

(22) Filed: Jan. 21, 2026

Related U.S. Application Data
(63) Continuation of application No. PCT/EP2024/071324, filed on Jul. 26, 2024.

(30) Foreign Application Priority Data
Jul. 27, 2023 (DE) 10 2023 207 185.1

(51) Int. Cl. G02B 26/08; G02B 26/10; G03F 7/00

(52) U.S. Cl. CPC G02B 26/0833; G02B 26/105; G03F 7/70141; G03F 7/70825; G03F 7/7085; G03F 7/70991

(57) ABSTRACT

A drive device for driving at least one actuator for actuating an optical element of an optical system comprises: an output stage configured to amplify an input voltage into a drive voltage for the actuator using a quiescent current of the output stage; and a providing device configured to set the quiescent current for the output stage depending on at least one parameter indicative of a power loss of the optical system.

### CROSS-REFERENCE TO RELATED APPLICATIONS

The present application is a continuation of, and claims benefit under 35 USC 120 to, international application No. PCT/EP2024/071324, filed Jul. 26, 2024, which claims benefit under 35 USC 119 of German Application No. 10 2023 207 185.1, filed Jul. 27, 2023. The entire disclosure of each of these applications is incorporated by reference herein.

### FIELD

The present disclosure relates to a drive device for driving at least one actuator of an optical system, to an optical system comprising such a drive device, and to a lithography apparatus comprising such an optical system.

### BACKGROUND

Microlithography apparatuses having actuatable optical elements, such as for example microlens arrays or micromirror arrays, are known. Microlithography is used to produce microstructured components, such as for example integrated circuits. The microlithography process is carried out using a lithography apparatus having an illumination system and a projection system.

Driven by the desire for ever smaller structures in the production of integrated circuits, EUV lithography apparatuses that use light at a wavelength in the range of 0.1 nm to 30 nm, for example 13.5 nm, are currently under development. Since most materials absorb light at this wavelength, such EUV lithography apparatuses typically use reflective optical units, i.e. mirrors, instead of refractive optical units, i.e. lens elements, as used previously.

The image of a mask (reticle) illuminated via the illumination system is projected by the projection system onto a substrate, for example a silicon wafer, which is coated with a light-sensitive layer (photoresist) and is arranged in the image plane of the projection system, in order to transfer the mask structure to the light-sensitive coating of the substrate. Actuatable optical elements can be used to improve the imaging of the mask on the substrate. For example, wavefront aberrations during exposure, which can result in magnified and/or blurred image representations, can be compensated for.

For example, a MEMS actuator (MEMS; microelectromechanical system) or a PMN actuator (PMN; lead magnesium niobate) may be used as actuator. A PMN actuator can enable path positioning in the sub-micrometer range or sub-nanometer range. In this case, the actuator, having actuator elements stacked one on top of another, can experience a force that causes a specific linear expansion as a result of a DC voltage being applied. The position set by way of the DC voltage (DC; direct current) may be adversely affected by external electromechanical crosstalk at the resonance points of the actuator driven by the DC voltage that arise as a matter of principle. MEMS mirrors and actuators suitable for driving them are described for example in DE 10 2016 213 025 A1. For precise actuator control, for example for a multiplicity of MEMS mirrors, a class A amplifier is desirable as an output stage because of the low signal distortion. However, class A amplifiers can have a relatively high quiescent current, which can lead to high waste heat.

For example, in MEMS systems, the micromirror arrays are usually not illuminated uniformly throughout. Depending on the illumination setting used, there may be large differences in the illumination of the different MEMS mirrors. The resulting temperature difference may lead to deformations on the mirror surface, since a reflection layer having a different temperature coefficient has been vapor-deposited onto the mirror surface of the MEMS mirror. Multiple heating and cooling after changing illumination settings may lead to increased material loading and thus to an increased probability of failure. Furthermore, such deformations may also have an influence on the system performance of the lithography apparatus.

### SUMMARY

The present disclosure seeks to improve the driving of an actuator of an optical system.

According to a first aspect, the disclosure proposes a drive device for driving at least one actuator. The drive device comprises:
an output stage configured to amplify an input voltage into a drive voltage for the actuator using a quiescent current of the output stage, and
a providing device configured to set the quiescent current for the output stage depending on at least one parameter indicative of a power loss of the optical system.

The optical system comprises a large number of optical elements, e.g. mirrors, for example MEMS mirrors, which are not illuminated uniformly throughout during operation. By virtue of the fact that the present providing device sets the quiescent current depending on the at least one parameter indicative of the power loss of the optical system, the providing device can influence and for example set the temperature of the assigned optical element by way of the setting of the quiescent current. This can reduce or compensate for temperature differences between illuminated and unilluminated optical elements. Consequently, the providing device, or—in the case of a plurality of drive devices—a plurality of providing devices, creates a temperature setting, for example a temperature regulation. This can provide increased temperature stability of the optical system, which reduces the probability of failure of components of the optical system.

In the present case, power loss of the optical system is taken to mean for example the thermal power loss of the optical system, for example the heat dissipation. Parameters which are indicative of the thermal power loss of the optical system are, for example, the temperature, for example the current temperature, of the optical element, the temperature, for example the current temperature, of the actuator and the temperature, for example the current temperature, of the drive device. For example, these components, that is to say the drive device, the assigned actuator and the assigned optical element, are thermally coupled to one another. The fact that the drive device is thermally coupled to the actuator and the optical element can result in the following. When the quiescent current is increased, the thermal power loss in the drive device increases, and the latter is heated. Consequently, the actuator and the optical element are concomitantly heated as a result of the thermal coupling. Consequently, the temperature of these components can be read back and influenced and regulated via the output stage. The present drive device may also be referred to as a drive device with dynamic quiescent current.

The quiescent current is for example the current that flows through the output stage, even if the latter is not dynamically active. The quiescent current is used to set the operating point at the output node. In the present case, this operating point is briefly shifted by the providing device depending on the desired property. The quiescent current may also be referred to as the bias current.

For example, the actuator is a MEMS actuator, a capacitive actuator, for example a PMN actuator (PMN; lead magnesium niobate), or a PZT actuator (PZT; lead zirconate titanate), or a LiNbO3 (lithium niobate) actuator. For example, the actuator is configured to actuate an optical element in the optical system. Examples of such an optical element comprise lens elements, mirrors and adaptive mirrors.

The optical system can be a projection optical unit of the lithography apparatus or projection exposure apparatus. However, the optical system can also be an illumination system. The projection exposure apparatus can be an EUV lithography apparatus. EUV stands for “extreme ultraviolet” and denotes a wavelength of the operating light of between 0.1 nm and 30 nm. The projection exposure apparatus can also be a DUV lithography apparatus. DUV stands for “deep ultraviolet” and denotes a wavelength of the operating light of between 30 nm and 250 nm.

According to one embodiment, the providing device is configured to set, for example regulate, the quiescent current for the output stage depending on the at least one parameter indicative of the power loss of the optical system and depending on a specific dynamic requirement for the output stage and/or a target position of the optical element.

The dynamic requirement specifies for example the desired dynamics of the output stage at a specific point in time. For example, if the capacitive actuator to be driven should undergo charge reversal quickly, the dynamic requirement is large, and the quiescent current is quickly increased. The following example may illustrate this. For example, the dynamic requirement is based on a change in the input voltage of the output stage, such as on a derivative of the input voltage du/dt. In this example, a high du/dt corresponds to a high dynamic requirement. As a result, the quiescent current is increased for example proportionally in the case of a high du/dt. In other words, du/dt is directly proportional to the change in the quiescent current. For a negative du/dt, the change and hence the effect in the other direction becomes effective. Here, the quiescent current is reduced, which can reduce the power consumption.

In other words, a high quiescent current is set in the case of a high dynamic requirement in order to be able to accordingly provide a short reaction time of the actuator. Otherwise, a small quiescent current can be used in order to minimize the associated waste heat. As a result, the temporarily increased quiescent current temporarily provides a high charge-reversal speed.

According to an embodiment, the at least one parameter indicative of the power loss of the optical system comprises:
a determined temperature of the optical element,
a determined temperature of the actuator,
a determined temperature of the drive device, and/or
a parameter derived from the measured quiescent current of the output stage.

According to an embodiment, the providing device is configured to set, for example regulate, the quiescent current for the output stage depending on the determined temperature of the optical element, a target temperature of the optical element, the determined temperature of the actuator, a target temperature of the actuator, the determined temperature of the drive device, a target temperature of the drive device, a specific dynamic requirement for the output stage and a target position of the optical element.

According to an embodiment, the drive device comprises a first temperature sensor assigned to the optical element and serving to provide the determined temperature of the optical element, a second temperature sensor assigned to the actuator and serving to provide the determined temperature of the actuator, a third temperature sensor assigned to the drive device and serving to provide the determined temperature of the drive device, and/or a determining unit configured to provide the parameter derived from the measured quiescent current of the output stage.

According to an embodiment, the output stage comprises an input node for receiving the input voltage of the output stage, an output node for providing the drive voltage to the actuator, and a transistor coupled between the input node and the output node and serving to amplify the input voltage into the drive voltage.

According to an embodiment, the providing device comprises a providing unit configured to set the quiescent current for the output stage depending on the at least one parameter indicative of the power loss of the optical system for the output stage and to feed it into the output node of the output stage.

According to an embodiment, the providing device comprises a control unit configured to provide a current depending on the at least one parameter indicative of the power loss of the optical system, the specific dynamic requirement for the output stage and/or the target position of the optical element, and a current mirror configured to mirror the current provided by the control unit for the purpose of providing the quiescent current and to feed the provided quiescent current into the output node of the output stage.

The control unit can be implemented for example in software, as a discrete circuit or as an ASIC. The current provided by the control unit can then be mirrored by the current mirror into the quiescent current in order to then feed the provided quiescent current into the output node of the output stage.

According to an embodiment, the control unit is configured to provide the current on the basis of a change in the input voltage of the output stage, for example on the basis of a derivative of the input voltage of the output stage.

According to an embodiment, the providing device comprises:
a controlling unit configured to provide a voltage depending on the at least one parameter indicative of the power loss of the optical system, the specific dynamic requirement for the output stage and/or the target position of the optical element,
a voltage-dependent current source configured to convert the voltage provided by the controlling unit into a current proportional thereto, and
a current mirror configured to mirror the converted proportional current for the purpose of providing the quiescent current and to feed the provided quiescent current into the output node of the output stage.

The controlling unit can be implemented for example in software, as a discrete circuit or as an ASIC. The voltage provided by the controlling unit can then be converted by the voltage-dependent current source into a current correspondingly proportional thereto. This converted current can be provided to the current mirror, which mirrors the converted proportional current and feeds it as a quiescent current into the output stage. The current mirror may also be referred to as a current mirror circuit.

According to an embodiment, the controlling unit is configured to provide the voltage provided by the controlling unit on the basis of a change in the input voltage of the output stage, for example on the basis of a derivative of the input voltage of the output stage.

According to an embodiment, the output stage comprises a class A amplifier. The class A amplifier exhibits only little signal distortion and therefore provides precise actuator control.

According to an embodiment, the output stage comprises a class AB amplifier. The class AB amplifier is a suitable alternative to the proposed class A amplifier.

According to an embodiment, the drive device comprises a plurality N of output stages for the respective driving of an actuator via a respective drive voltage. In this case, the current mirror can be configured to mirror the current which is indicative of the specific dynamic requirement N-fold for the purpose of providing a respective quiescent current and to feed the respectively provided quiescent current into the respective output node of the respective output stage.

This embodiment is particularly desirable when a multiplicity N of optical elements are to be driven by a corresponding multiplicity N of actuators. In this embodiment, only a single current mirror is then used for driving the N actuators, which current mirror mirrors the current indicative of the specific dynamic requirement, valid for all N actuators, N-fold in order to provide a respective quiescent current for the respective output stage. A further desirable feature, in addition to the use of a smaller number of component parts, to be specific only one current mirror, is that the N output stages can be driven identically.

The respective unit, for example the control unit, can be implemented in hardware and/or software. In the case of a hardware implementation, the unit can be embodied as a device or as part of a device, for example as a computer or as a microprocessor or as part of the control device. In the case of a software implementation, the unit can be embodied as a computer program product, as a function, as a routine, as part of a program code or as an executable object.

According to a second aspect, the disclosure proposes an optical system comprising a plurality of actuatable optical elements, wherein each of the actuatable optical elements of the number is assigned an actuator, wherein each actuator is assigned a drive device for driving the actuator according to the first aspect or according to one of the embodiments of the first aspect.

The optical system comprises for example a micromirror array and/or a microlens array having a multiplicity of mutually independently actuatable optical elements.

In embodiments, groups of actuators can be defined, wherein all actuators of a group are assigned the same drive device.

According to one embodiment, the optical system is embodied as an illumination optical unit or as a projection optical unit of a lithography apparatus.

According to an embodiment, the optical system comprises a vacuum housing, in which the actuatable optical elements, the assigned actuators and the drive device are arranged.

According to a third aspect, the disclosure proposes a lithography apparatus comprising an optical system according to the second aspect or according to one of the embodiments of the second aspect.

The lithography apparatus is for example an EUV lithography apparatus, the operating light of which is in a wavelength range of 0.1 nm to 30 nm, or a DUV lithography apparatus, the operating light of which is in a wavelength range of 30 nm to 250 nm. “A” or “an” or “one” in the present case should not necessarily be understood as being restrictive to exactly one element. Rather, a plurality of elements, such as for example two, three or more, can also be provided. Nor should any other numeral used here be understood to the effect that there is a restriction to exactly the stated number of elements. Rather, numerical deviations upward and downward are possible, unless indicated otherwise.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject matter of the dependent claims and also of the exemplary embodiments of the disclosure that are described below. The disclosure is explained in greater detail hereinafter on the basis of certain embodiments with reference to the appended figures.

### BRIEF DESCRIPTION OF THE DRAWINGS

FIG. 1 shows a schematic meridional section through a projection exposure apparatus for EUV projection lithography;

FIG. 2 shows a schematic illustration of one embodiment of an optical system;

FIG. 3 shows a schematic block diagram of a first embodiment of a drive device for driving an actuator for actuating an optical element of an optical system;

FIG. 4 shows a schematic block diagram of a second embodiment of a drive device for driving an actuator for actuating an optical element of an optical system; and

FIG. 5 shows a schematic block diagram of a third embodiment of a drive device for driving an actuator for actuating an optical element of an optical system.

### DETAILED DESCRIPTION

In the figures, identical or functionally identical elements have been provided with the same reference signs, unless indicated otherwise. Furthermore, it should be noted that the illustrations in the figures are not necessarily true to scale.

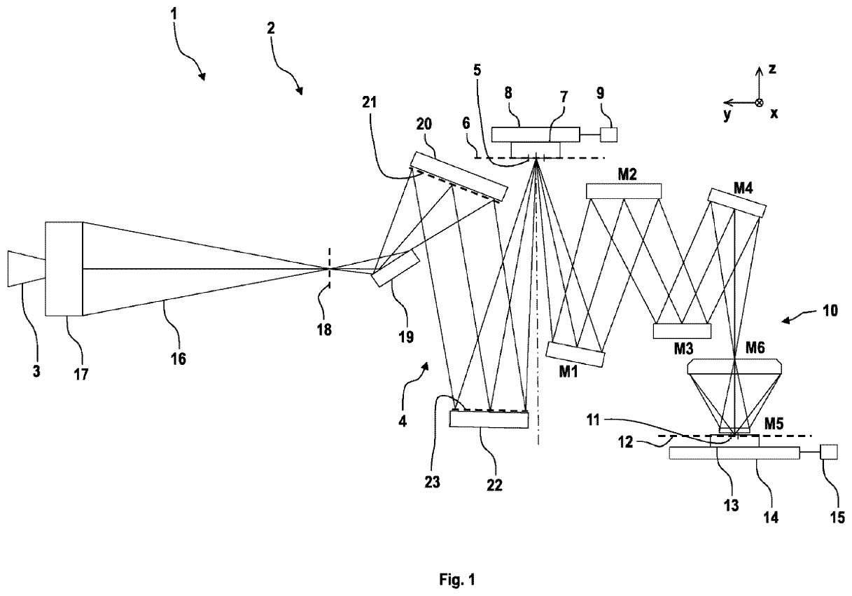

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, for explanation purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example along the y-direction y. The displacement, firstly, of the reticle 7 by way of the reticle displacement drive 9 and, secondly, of the wafer 13 by way of the wafer displacement drive 15 can be implemented so as to be synchronized with one another.

The light source 3 is an EUV radiation source. The light source 3 emits for example EUV radiation 16, which is also referred to below as used radiation, illumination radiation or illumination light. The used radiation 16 has for example a wavelength in the range of between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be a free electron laser (FEL).

The illumination radiation 16 emanating from the light source 3 is focused by a collector 17. The collector 17 can be a collector with one or with a plurality of ellipsoidal and/or hyperboloidal reflection surfaces. The at least one reflection surface of the collector 17 can be impinged on by the illumination radiation 16 with grazing incidence (GI), i.e. with angles of incidence greater than 45°, or with normal incidence (NI), i.e. with angles of incidence less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the pure deflection effect. Additionally or alternatively, the deflection mirror 19 can be embodied as a spectral filter that separates a used light wavelength of the illumination radiation 16 from extraneous light of a wavelength differing therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 can be embodied as macroscopic facets, for example as rectangular facets or as facets with an arcuate or partly circular edge contour. The first facets 21 can be embodied as plane facets or alternatively as convexly or concavely curved facets.

As is known from DE 10 2008 009 600 A1, for example, the first facets 21 themselves can each also be composed of a multiplicity of individual mirrors, for example a multiplicity of micromirrors. The first facet mirror 20 can be embodied for example as a microelectromechanical system (MEMS system). For details, reference is made to DE 10 2008 009 600 A1.

The illumination radiation 16 travels horizontally, i.e. along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 thus forms a doubly faceted system. This fundamental principle is also referred to as a fly's eye condenser (or fly's eye integrator).

It can be desirable to arrange the second facet mirror 22 not exactly in a plane that is optically conjugate to a pupil plane of the projection optical unit 10. For example, the second facet mirror 22 can be arranged so as to be tilted in relation to a pupil plane of the projection optical unit 10, as described for example in DE 10 2017 220 586 A1.

The individual first facets 21 are imaged into the object field 5 with the aid of the second facet mirror 22. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can have exactly one mirror, or alternatively two or more mirrors arranged one behind another in the beam path of the illumination optical unit 4. The transfer optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, the deflection mirror 19 can also be omitted, and so the illumination optical unit 4 can have exactly two mirrors downstream of the collector 17 in that case, specifically the first facet mirror 20 and the second facet mirror 22.

The imaging of the first facets 21 into the object plane 6 via the second facets 23 or using the second facets 23 and a transfer optical unit is regularly only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6, and can be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image shift in the y-direction y between a y-coordinate of a center of the object field 5 and a y-coordinate of the center of the image field 11. This object-image shift in the y-direction y can be of approximately the same magnitude as a z-distance between the object plane 6 and the image plane 12.

The projection optical unit 10 can be embodied for example in anamorphic fashion. It has for example different imaging scales βx, βy in the x-and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, that is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case one of the second facets 23 is assigned to exactly one of the first facets 21 in order to form a respective illumination channel for illuminating the object field 5. For example, this can result in illumination according to the Köhler principle. The far field is decomposed into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

The projection optical unit 10 can have for example a homocentric entrance pupil. The latter can be accessible. It can also be inaccessible.

The entrance pupil of the projection optical unit 10 regularly cannot be exactly illuminated using the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area constitutes the entrance pupil or an area conjugate thereto in real space. For example, this area exhibits a finite curvature.

It may be the case that the projection optical unit 10 has different poses of the entrance pupil for the tangential beam path and for the sagittal beam path. In this case, an imaging element, for example an optical component of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

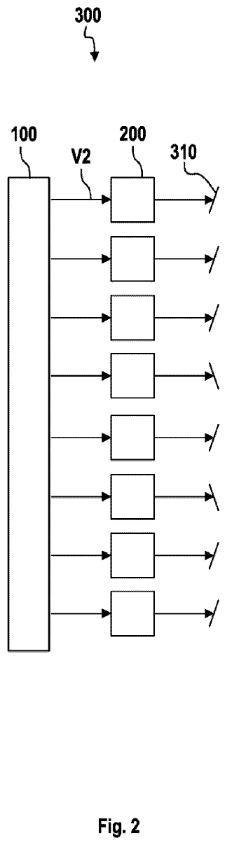

FIG. 2 shows a schematic illustration of one embodiment of an optical system 300 for a lithography apparatus or projection exposure apparatus 1, as shown for example in FIG. 1. Additionally, the optical system 300 in FIG. 2 can also be used in a DUV lithography apparatus, for example.

The optical system 300 in FIG. 2 has a plurality of actuatable optical elements 310. The optical system 300 is embodied here as a micromirror array, wherein the optical elements 310 are micromirrors. Each micromirror 310 is actuatable viaan assigned actuator 200. For example, a respective micromirror 310 can be tilted about two axes and/or displaced in one, two or three spatial axes via the assigned actuator 200. The reference signs only of the topmost row of these elements are depicted, for reasons of clarity.

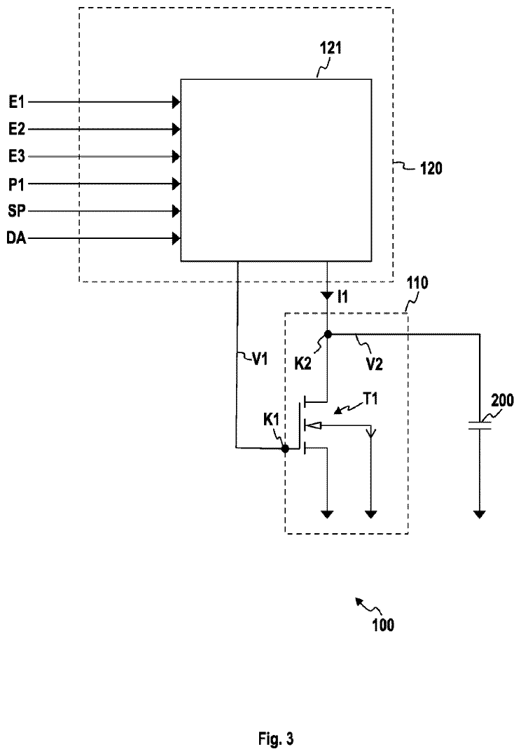

The drive device 100 drives the respective actuator 200, for example using a drive voltage V2 (see FIGS. 3 to 5). A position of the respective micromirror 310 is thus set. The drive device 100 is described with reference to FIGS. 3 to 5 for example.

FIG. 3 illustrates a schematic block diagram of a first embodiment of a drive device 100 for driving an actuator 200 for actuating an optical element 310 of an optical system 300. The actuator 200 is a capacitive actuator in the embodiments in FIGS. 3 to 5 and is shown as a capacitor in these FIGS. 3 to 5.

The drive device 100 according to FIG. 3 comprises an output stage 110 and a providing device 120.

The output stage 110 is configured to amplify an input voltage V1 into a drive voltage V2 for the actuator 200 using a quiescent current I1 of the output stage 110. The output stage 110 can be designed as a class A amplifier and comprises a transistor T1. For example, the transistor T1 is a field effect transistor (FET). Alternatively, the transistor T1 can also be designed as a bipolar transistor. As an alternative to the class A amplifier, the output stage 110 can also be designed as a class AB amplifier.

The output stage 110 comprises an input node K1 for receiving the input voltage V1, an output node K2 for providing the drive voltage V2 to the actuator 200, and the transistor T1 coupled between the input node K1 and the output node K2 and serving to amplify the input voltage V1 into the drive voltage V2.

The providing device 120 in FIG. 3 is configured to set the quiescent current I1 for the output stage 110 depending on at least one parameter E1, E2, E3, P1 indicative of a power loss of the optical system 300. Examples of the at least one parameter E1, E2, E3, P1 indicative of the power loss of the optical system 300 include a determined temperature E1 of the optical element 310, a determined temperature E2 of the actuator 200, a determined temperature E3 of the drive device 100 and/or a parameter P1 derived from the measured quiescent current I1 of the output stage 110.

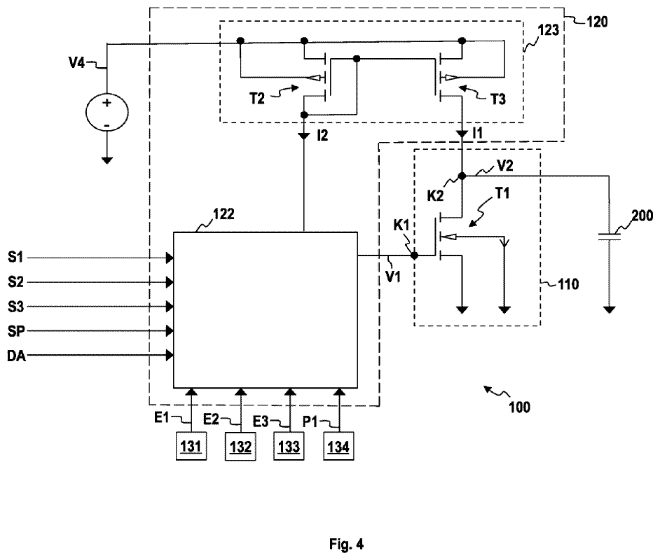

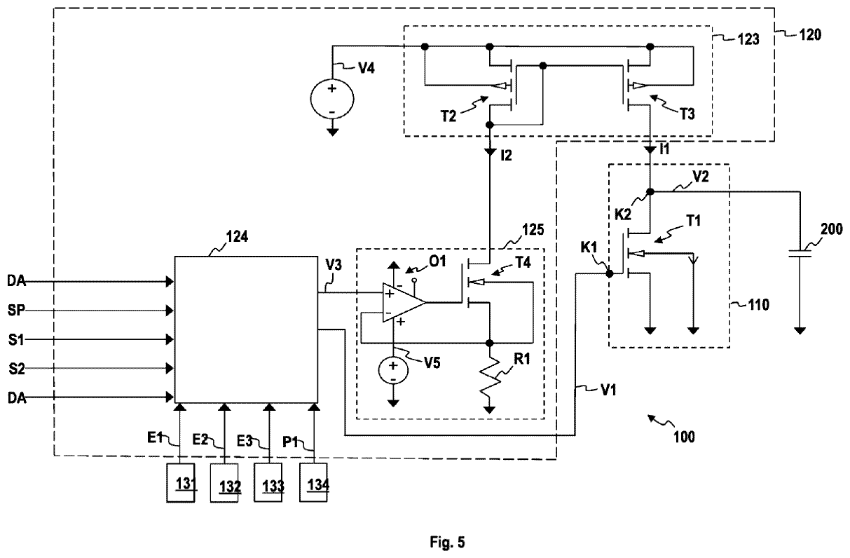

In order to determine the temperature E1, for example the current temperature E1, of the optical element 310, a temperature sensor 131 assigned to the optical element 310 (see FIGS. 4 and 5) can be used. Alternatively, the temperature E1 of the optical element 310 can be derived from another temperature measured in the optical system 300. Accordingly, the temperature E2 of the actuator 200 can be determined by way of a temperature sensor 132 assigned to the actuator 200 (see FIGS. 4 and 5). Alternatively, the temperature E2 of the actuator 200, that is to say for example the current temperature E2 of the actuator 200, can also be derived by way of another temperature measured in the optical system 300. The temperature E3 of the drive device 100 can be measured by way of a temperature sensor 133 assigned to the drive device 100 (see FIGS. 4 and 5). Alternatively, the temperature E3, for example the current temperature E3, of the drive device 100 can be derived from another temperature measured in the optical system 300. In order to provide the parameter P1, for example, the quiescent current I1 flowing into the output node K2 is measured, and a temperature or a resulting waste heat is determined. The resulting waste heat can correspond for example to the derived parameter P1.

As illustrated in FIG. 3, the providing device 120 has a providing unit 121. The providing unit 121 in FIG. 3 receives the determined temperature E1 of the optical element 310, the determined temperature E2 of the actuator 200, the determined temperature E3 of the drive device 100, the parameter P1 derived from the measured quiescent current I1 of the output stage 110, a target position SP of the optical element 310 and a specific dynamic requirement DA for the output stage 110.

The providing unit 121 is configured here to set, for example regulate, the quiescent current I1 for the output stage 110 depending on the determined temperature E1 of the optical element 310, the determined temperature E2 of the actuator 200, the determined temperature E3 of the drive device 100, the parameter P1 derived from the measured quiescent current E1 of the output stage 110, the specific dynamic requirement DA for the output stage 110 and/or the target position SP of the optical element 310. Furthermore, the providing unit 121 is also configured to provide the input voltage V1 for the output stage 110 on the basis of the received parameters, namely E1, E2, E3, P1, SP and/or DA.

The dynamic requirement DA can have been predefined or can be predefined for example by a control device (not shown) of the optical system 300.

FIG. 4 shows a schematic block diagram of a second embodiment of a drive device 100 for driving an actuator 200 for actuating an optical element 310 of an optical system 300.

The second embodiment according to FIG. 4 differs from the first embodiment according to FIG. 3 in terms of the configuration of the providing device 120.

The providing device 120 according to FIG. 4 comprises a control unit 122 and a current mirror 123. The current mirror 123 may also be referred to as a current mirror circuit.

Furthermore, FIG. 4 shows the first temperature sensor 131 assigned to the optical element 310 and serving to provide the determined temperature E1 of the optical element 310, the second temperature sensor 132 assigned to the actuator 200 and serving to provide the determined temperature E2 of the actuator 200, the third temperature sensor 133 assigned to the drive device 100 and serving to provide the determined temperature E3 of the drive device 100, and a determining unit 134 configured to provide the parameter P1 derived from the measured quiescent current I1 of the output stage 110. The first temperature sensor 131, the second temperature sensor 132, the third temperature sensor 133 and the determining unit 134 are coupled to the control unit 122 and provide the parameters E1, E2, E3 and P1 to said control unit. Further, the control unit 122 receives a target temperature S1 of the optical element 310, a target temperature S2 of the actuator 200, a target temperature S3 of the drive device 100, the target position SP of the optical element 310 and the specific dynamic requirement DA for the output stage 110. The received target temperatures S1, S2, S3 are used for respective comparison with the respective currently determined temperatures E1, E2, E3. In the embodiment according to FIG. 4, the determined temperature E1, the determined temperature E2, the determined temperature E3 and the derived parameter P1 form the parameters E1, E2, E3, P1 indicative of the thermal power loss of the optical system 300.

In this case, the control unit 122 is configured to provide a current I2 depending on the parameters E1, E2, E3, P1 indicative of the thermal power loss of the optical system 300, the target temperatures S1, S2, S3 as reference, the target position SP of the optical element 310 and/or the specific dynamic requirement DA for the output stage 110. In an analogous manner, the control unit 122 is configured to also provide the input voltage V1 for the output stage 110 at the input node K1 of the output stage 110.

The current mirror 123 is supplied with a positive supply voltage V4 and is configured, via its transistors T1 and T2, to mirror the current I2 provided by the control unit 122 for the purpose of providing the quiescent current I1 and to feed the provided quiescent current I1 into the output node K2 of the output stage 110.

FIG. 5 shows a schematic block diagram of a third embodiment of a drive device 100 for driving an actuator 200 for actuating an optical element 310 of an optical system 300. The third embodiment according to FIG. 5 differs from the embodiments according to FIGS. 3 and 4 in terms of the configuration of the providing device 120.

The providing device 120 according to FIG. 5 comprises a controlling unit 124, a voltage-dependent current source 125, and a current mirror 123.

The controlling unit 124 is configured to provide a voltage V3 depending on the parameters E1, E2, E3, P1 indicative of the power loss of the optical system 300, the target temperatures S1, S2, S3, the target position SP, the specific dynamic requirement DA and/or the derived parameter P1.

The voltage-dependent current source 125 is configured to convert the voltage V3 provided by the controlling unit 124 into a current I2 proportional thereto. Furthermore, the controlling unit 124 is also configured to provide the input voltage V1 for the output stage 110 depending on the received parameters E1-E3, S1-S3, SP, DA and/or P1 at the input node K1 of the output stage 110.

The voltage-dependent current source 125 comprises an operational amplifier O1, which is supplied via a supply voltage V5, a transistor T4, for example a field effect transistor, and a resistor R1. The resistor R1 is coupled to the inverting input of the operational amplifier O1 and to the transistor T4, as shown in FIG. 5. The transistor T4 provides the converted proportional current I2 to the current mirror 123 on the output side. The current mirror 123 is embodied as explained with regard to FIG. 4. Consequently, the current mirror 123 is configured to mirror the converted proportional current I2 for the purpose of providing the quiescent current I1 and to feed the provided quiescent current I1 into the output node K2 of the output stage 110.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Drive device
110 Output stage
120 Providing device
121 Providing unit
122 Control unit
123 Current mirror
124 Controlling unit
125 Voltage-dependent current source
131 Temperature sensor
132 Temperature sensor
133 Temperature sensor
134 Determining unit
200 Actuator
300 Optical system
310 Optical element
DA Dynamic requirement
E1 Determined temperature of the optical element
E2 Determined temperature of the actuator
E3 Determined temperature of the drive device
I1 Quiescent current
I2 Indicative current
K1 Input node of the output stage
K2 Output node of the output stage
M1 Mirror
M2 Mirror
M3 Mirror
M4 Mirror
M5 Mirror
M6 Mirror
O1 Operational amplifier
R1 Resistor
S1 Target temperature of the optical element
S2 Target temperature of the actuator
S3 Target temperature of the drive device
SP Target position of the optical element

T1 Transistor

T2 Transistor

T3 Transistor

T4 Transistor
V1 Input voltage
V2 Drive voltage
V3 Indicative voltage
V4 Supply voltage
V5 Supply voltage

What is claimed is:

1. A drive device configured to drive an actuator to actuate an optical element of an optical system, the drive device comprising:
an output stage configured to amplify an input voltage into a drive voltage for the actuator via a quiescent current of the output stage; and
a providing device configured to set the quiescent current for the output stage depending on at least parameter selected from the group consisting of a determined temperature of the optical element, a target temperature of the optical element, a determined temperature of the actuator, a target temperature of the actuator, a determined temperature of the drive device, a target temperature of the drive device, a specific dynamic requirement for the output stage, and a target position of the optical element.

2. The drive device of claim 1, wherein the providing device is further configured to set the quiescent current for the output stage depending on a specific dynamic requirement for the output stage and/or a target position of the optical element.

3. The drive device of claim 2, wherein the at least one parameter comprises at least one member selected from the group consisting of the determined temperature of the optical element, the determined temperature of the actuator, the determined temperature of the drive device, and a parameter derived from a measured quiescent current of the output stage.

4. The drive device of claim 1, further comprising:
a first temperature sensor assigned to the optical element and configured to provide the determined temperature of the optical element;
a second temperature sensor assigned to the actuator and configured provide the determined temperature of the actuator;
a third temperature sensor assigned to the drive device and configured to provide the determined temperature of the drive device; and/or
a determining unit configured to provide the parameter derived from a measured quiescent current of the output stage.

5. The drive device of claim 1, wherein the output stage comprises:
an input node configured to receive the input voltage of the output stage;
an output node configured to provide the drive voltage to the actuator; and
a transistor coupling the input node and the output node, the transistor configured to amplify the input voltage into the drive voltage.

6. The drive device of claim 5, wherein the providing device comprises a providing unit configured to: i) set the quiescent current for the output stage depending on the at least one parameter; and ii) provide the quiescent current to the output node of the output stage.

7. The drive device of claim 5, wherein the providing device comprises:
a control unit configured to provide a current depending on the at least one parameter and at least one additional parameter selected from the group consisting of a specific dynamic requirement for the output stage and a target position of the optical element;
a current mirror configured to: i) mirror the current provided by the control unit to provide the quiescent current; and ii) provide the quiescent current to the output node of the output stage.

8. The drive device of claim 7, wherein the control unit is configured to provide the current to provide the quiescent current based on a change in the input voltage of the output stage.

9. The drive device of claim 7, wherein the control unit is configured to provide the current to provide the quiescent current based on a derivative of the input voltage of the output stage.

10. The drive device of claim 5, wherein the providing device comprises:
a controlling unit configured to provide a voltage depending on the at least one parameter and at least one additional parameter selected from the group consisting of a specific dynamic requirement for the output stage and a target position of the optical element;
a voltage-dependent current source configured to convert the voltage provided by the controlling unit into a current proportional thereto; and
a current mirror configured to: i) mirror the converted proportional current to provide the quiescent current; and ii) provide the quiescent current to the output node of the output stage.

11. The drive device of claim 10, wherein the controlling unit is configured to provide the voltage provided by the controlling unit based on a change in the input voltage of the output stage.

12. The drive device of claim 10, wherein the controlling unit is configured to provide the voltage provided by the controlling unit based on a derivative of the input voltage of the output stage.

13. The drive device of claim 7, wherein:
the drive device comprises a plurality N of output stages, each output stage configured to drive the actuator via a respective drive voltage;
the current mirror is configured to mirror the current N-fold to: i) provide a respective quiescent current; and ii) provide the respectively provided quiescent current to a respective output node of the respective output stage.

14. The drive device of claim 1, wherein the providing device configured to regulate the quiescent current for the output stage depending on the at least parameter.

15. The drive device of claim 14, wherein the providing device is further configured to regulate the quiescent current for the output stage depending on at least one additional parameter selected from the group consisting of a specific dynamic requirement for the output stage and a target position of the optical element.

16. The drive device of claim 15, wherein the at least one parameter comprises at least one member selected from the group consisting of the determined temperature of the optical element, the determined temperature of the actuator, the determined temperature of the drive device, and a parameter derived from a measured quiescent current of the output stage.

17. An optical system, comprising:
a plurality of optical elements;
a plurality of actuators, each actuator configured to actuate a corresponding optical element; and
a plurality of drive devices,
wherein:
each actuator is assigned a corresponding drive device to drive the actuator; and
for at least one of the drive devices, the drive device comprises:
an output stage configured to amplify an input voltage into a drive voltage for the assigned actuator via a quiescent current of the output stage; and
a providing device configured to set the quiescent current for the output stage depending on at least parameter selected from the group consisting of a determined temperature of the optical element assigned to the actuator which is assigned to the drive device, a target temperature of the optical element assigned to the actuator which is assigned to the drive device, a determined temperature of the actuator assigned to the drive device, a target temperature of the actuator assigned to the drive device, a determined temperature of the drive device, a target temperature of the drive device, a specific dynamic requirement for the output stage, and a target position of the optical element assigned to the actuator which is assigned to the drive device.

18. The optical system of claim 17, wherein the optical system is an illumination optical unit of a lithography apparatus, or the optical system is a projection optical unit of a lithography apparatus.

19. An apparatus, comprising:
an illumination optical unit; and
a projection optical unit,
wherein the illumination optical unit comprises an optical system according to

17.

20. An apparatus, comprising:
an illumination optical unit; and
a projection optical unit,
wherein the illumination optical unit comprises an optical system according to claim 17.
